(19) United States
(12) Patent Application Publication
(10) Pub. No.: US 2016/0131728 A1
(43) Pub. Date: May 12, 2016

(54) MR LOCAL COIL SYSTEM, MR SYSTEM AND METHOD OF OPERATION

(71) Applicants: Stephan Biber, Erlangen (DE); Klaus Huber, Effeltrich (DE); Johanna Dorothee Schöpfer, Erlangen (DE); Markus Vester, Nurnberg (DE)

(72) Inventors: Stephan Biber, Erlangen (DE); Klaus Huber, Effeltrich (DE); Johanna Dorothee Schöpfer, Erlangen (DE); Markus Vester, Nurnberg (DE)

(21) Appl. No.: 14/938,707

(22) Filed: Nov. 11, 2015

(30) Foreign Application Priority Data
Nov. 11, 2014 (DE) 102014222938.3

(51) Int. Cl. G01R 33/483

(52) U.S. Cl. CPC G01R 33/4831

(57) ABSTRACT

A magnetic resonance (MR) local coil system includes local MR transmit coils that may be inductively coupled to at least one power-feed coil of an MR device. At least two local MR transmit coils may be used to generate local B1 excitation fields that are differently structured with respect to each other.

This application claims the benefit of DE 10 2014 222 938.3, filed on Nov. 11, 2014, which is hereby incorporated by reference in its entirety.

### BACKGROUND

The present embodiments relate to a magnetic resonance (MR) local coil system, an MR system, and a method to operate an MR system.

In MR tomography, very strong peak RF magnetic fields (B1) are used for the excitation of spins, for example, by sequences adapted for imaging in an environment of metallic implants. This includes the B1 excitation field (also known as a transmit B1 field or B1 TX field) being as homogeneous as possible in an associated examination volume. It is also desirable for the smallest possible RF magnetic field to be generated outside the examination volume in order to reduce the stress on a patient due to heating. An associated characteristic for the thermal stress is the specific absorption rate (SAR).

A body coil (e.g., a whole body transmit antenna using the principle of a birdcage resonator) has been used to excite the spins. The B1 excitation field generated thereby may not be restricted to specific examination volumes so that relatively high RF power levels are to be provided. For example, it is not yet possible to meet the above-described requirements for high peak B1 magnetic fields and low global SAR stress with the currently usual whole-body transmit antennas to a satisfactory degree.

DE 35 00 456 A1 discloses a coil arrangement for an NMR examination device for collecting NMR information on an object to be examined. The arrangement includes first coil elements for the excitation of the nuclei of an area of an object and for receiving a signal emitted by the nuclei of an area of an object. The arrangement further includes further second coil elements for gaining the amplitude of a signal emitted by a limited region of the object and connected to the first coil elements. The gaining is in proportion to the amplitude of a signal resulting from other regions of an object. This is intended to provide a method for improving the ratio of a signal connection, and to be precise originating from the limited region of the object to the first coil elements to the electric noise created in the signal collection unit and in the object. This may be applied with NMR imaging units, which, in addition to mapping the entire body, may be used for the examination of smaller subdomains such as eyes, ears, limbs, etc.

A local receiver output is provided to control these local transmit coils, which provides a significant additional considerable additional technical effort for the power electronics of an MR system. Wang et al, Inductive Coupled Local TX Coil Design, Proc. Intl. Soc. Mag. Reson. Med. 18 (2010) describes the excitation of a knee coil via inductive coupling-in of the power emitted by the whole-body coil. This is comparable with focusing the B1-TX magnetic field generated by the whole-body transmit antenna on the volume enclosed by the local transmit coil and results in a greatly reduced power requirement.

For example, U.S. Pat. No. 6,380,741 B1 or Johanna Schopfer et al., A novel design approach for planar local transmit/receive antennas in 3T spine imaging, Proc. Intl. Soc. Mag. Reson. Med. 22 (2014), page 1313, discloses body coils for MR applications with a loop-butterfly structure.

### SUMMARY AND DESCRIPTION

The scope of the present invention is defined solely by the appended claims and is not affected to any degree by the statements within this summary.

The present embodiments may obviate one or more of the drawbacks or limitations in the related art. For example, a possibility for local generation of strong B1 excitation fields with a low global SAR value, which may be implemented in a simple and economical way and enables accurate imaging, is provided.

A magnetic resonance (MR) local coil system includes a plurality of local MR transmit coils that may be inductively coupled to at least one power-feed coil of an MR device. At least two local MR transmit coils may be used to generate local B1 excitation fields that are differently structured with respect to each other. Therefore, the local MR transmit coils may be fed by inductive coupling to a B1 excitation field generated by at least one power-feed coil (hereinafter, without restricting the generality, also a “global B1 excitation field”).

An MR local coil system of this kind enables focusing of the transmit field by the local MR transmit coils. The local MR transmit coils in each case generate in an immediate environment associated B1 excitation fields (hereinafter, without restricting the generality, also “local B1 excitation fields”) and, as a result, are, for example, particularly suitable for imaging in the region of an implant (e.g., reduction of metal artifacts). The inductive coupling simplifies the system architecture because no wire-bound transmit path is required. In order to avoid losses, the inductive coupling is resonant.

In addition, the only locally high field strengths in the vicinity of a patient enable SAR limit values to be kept low.

For example, if the at least one fixed power-feed coil in the device is embodied as at least one body coil of an MR device, and the MR local coil system is located inside the body coil, the advantage is obtained that the very narrow SAR limit values due to contact protection for the body coil may be shifted in favor of a higher RF power since the body coil now needs less current to generate the stronger local B1 excitation field required in the field of view of the inductively coupled MR transmit coil(s). The higher RF power may be used to measure more slices with one measurement.

The MR local coil system is also, for example, provided for use in an MR device (e.g., for positioning inside a body coil of the MR-device). However, the MR local coil system does not itself need to be part of the MR device. Apart from the plurality of local MR transmit coils, the MR local coil system may include a holder for the MR transmit coils that defines the positioning of the local MR transmit coils in relation to each other and also serves to protect the local MR transmit coils against mechanical stress. The holder may be rigid or deformable. The holder may also, for example, be embodied in the form of a patient bench in which the local MR transmit coils are integrated (e.g., for a more accurate examination of a spine).

The local MR transmit coils may generate a circularly polarized local B1 excitation field and/or a local B1 excitation field that is linearly polarized in one or more polarization directions.

The local MR transmit coil may also be referred to as a local coil.

A coil may also be referred to as an antenna.

The fact that local B1 excitation fields that are differently structured with respect to each other may be or are generated by at least two local MR transmit coils may provide that a different local B1 excitation field is generated by at least two local MR transmit coils (e.g., in the case of conditions that are otherwise the same, such same position, alignment and/or same global B1 excitation field).

The expression “(global or local) B1 excitation fields differently structured in relation to each other” may, for example, be B1 excitation fields that have a different basic shape and/or alignment in relation to each other. In an additional or alternative embodiment, B1 excitation fields that are differently structured with respect to each other have a different polarization.

In a development, the plurality of local MR transmit coils have two or more different physical embodiments. For example, the MR local coil system may include two groups of local MR transmit coils that are the same within the corresponding group but different on a group-wise basis.

In one embodiment, at least two of the local MR transmit coils are transmit coils that are planar with respect to each other. For example, a plurality of local MR transmit coils, by which local B1 excitation fields differently structured with respect to each other may be generated, may be arranged in a planar manner in relation to each other. In one embodiment, all local MR transmit coils may be arranged in a planar manner in relation to each other.

In one development, MR transmit coils that are planar with respect to each other generate local B1 excitation fields with a different polarization (e.g., with linear polarization directed orthogonally in relation to each other).

In yet another embodiment, the at least one local MR transmit coil may be or is operated as a pure transmit coil (e.g., only for focusing the transmit field). For example, all local MR transmit coils may be operated as pure transmit coils.

In a further embodiment, the at least one local MR transmit coil may be or is operated as a transmit/receive coil. For example, an even higher local measuring and image resolution may be achieved. For example, all local MR transmit coils may be operated as transmit/receive coils.

For example, the at least one MR transmit coil may be or is operated not only as a receive coil.

In a further embodiment, the MR local coil system includes as MR transmit coils at least one circular-loop coil and at least one butterfly coil. For example, a loop coil and a butterfly coil may form a common loop-butterfly structure (e.g., a planar loop-butterfly structure). This may also be understood as providing that a local MR transmit coil is used in a loop-butterfly structure that has a loop part and a butterfly part. This embodiment has the advantage that the loop coil and the butterfly coil may be used separately for the focusing of an x- or y-polarized field component of a global B1 excitation field of the at least one power-feed coil. The loop coil and the butterfly coil are, for example, orthogonal and consequently in each case may only be coupled with one of the two differently polarized global B1 field components of the at least one power-feed coil. Therefore, the global B1 transmit field profile may be defined by different amplitudes and phase angles of two individually controllable part-systems or part-regions of the at least one power-feed coil (e.g., body coil) that respectively generate a polarized global B1 field component. The greatly different global B1 excitation field components or B1 excitation field distributions that may be generated in this way offer advantages, for example, during the use of parallel transmission techniques (“pTX”). Such differently polarized global B1 excitation field components may, for example, be achieved with MR devices or MR systems with an at least two-channel transmitter architecture.

For example, the loop coil and the butterfly coil or the “loop” part and the “butterfly” part of the local MR transmit coil may be coupled with global B1 excitation field components of the at least one power-feed coil that are polarized orthogonally in relation to each other (e.g., the loop coil with the x-polarized field component of the global B1 excitation field and the butterfly coil with the y-polarized field component of the global B1 excitation field). The loop coil and the butterfly coil may also generate local B1 excitation fields that are polarized orthogonally in relation to each other.

In one embodiment, using a common loop-butterfly structure, with simultaneous excitation of the two coils, by superimposition of the associated local x- or y-polarized B1 excitation fields, circularly polarized local B1 excitation fields may be created. In another embodiment, by coupling the loop-butterfly structure with a circularly polarized B1 excitation field, a circularly polarized local B1 excitation field may be created. Therefore, the loop-butterfly structure also enables both single-channel and two-channel transmission operation of the MR system.

Additionally or alternatively, apart from the loop coil and the butterfly coil, the local MR transmit coils may also include coils with any other suitable shape enabling coupling with, for example, differently polarized global B1 excitation field components and/or the generation of differently structured (e.g., polarized, local B1 excitation fields).

In yet a further embodiment, at least one local MR transmit coil includes a detuning circuit or is connected to such a circuit, by which the coupling to the at least one power-feed coil or the global B1 excitation field thereof may be optionally activated and deactivated. The detuning circuit may be used for the optional activation of the associated MR transmit coil for the transmission (and effects, for example, the above-addressed focusing of the global B1 excitation field onto the environment of the MR transmit coil) or the deactivation thereof so that no change to the original global B1 excitation field is effected. Each local MR transmit coil may be assigned a respective detuning circuit, or at least two local MR transmit coils (e.g., including different local MR transmit coils) may be assigned a common detuning circuit. Detuning circuits for the MR field are, for example, known from DE 100 51 155 A1. The detuning circuit has sufficient power durability for operation in the B1 excitation field.

In one embodiment, an MR system including an MR device with at least one power-feed coil and including at least one MR local coil system, as described above, is provided. The local MR transmit coils of the at least one MR local coil system may be inductively coupled with the at least one power-feed coil. The MR device is configured for the selective generation of differently structured global B1 field components of a global B1 excitation field that may be generated by the at least one power-feed coil. Different MR transmit coils of the local MR local coil system may be coupled with differently structured global B1 field components.

The MR system has the same advantages as the localized MR local coil system and may be embodied analogously. In addition, the selective generation of the differently structured global B1 field components (e.g., multiple channels) and the coupling thereof in each case with only one part of the local MR transmit coils may generate a particularly multifarious B1 excitation, thus facilitating analysis.

To enable multiple channels, the at least one power-feed coil may include two or more groups or part-systems that may be controlled independently of each other (without restricting generality, also with prespecified parameter values). In a development thereof, the power-feed coil includes a plurality of B1 transmit coils or feed points that may be controlled separately in at least two groups or part systems. The groups may be used to generate a respectively structured component (e.g., global B1 excitation field) of a global B1 excitation field. The global B1 excitation field components that may be generated very differently facilitate, for example, the use of parallel transmission techniques (pTX) with the MR device.

For example, using two groups, an x-polarized field component or a y-polarized field component may be generated, or the differently structured global B1 field components may be B1 field components that are linearly polarized in the x-direction or y-direction. However, in one mode of operation of the MR-device, the different groups may also be operated in the same way.

In a further embodiment, the MR transmit coils are embodied such that the MR transmit coils generate a local B1 excitation field that is similar to the structured global B1 field components coupled therewith in each case (e.g., has linear polarization in the same direction as the feeding global B1 excitation field component).

The at least one power-feed coil may be embodied as at least one body coil. The body coil may, for example, include a plurality of feed points. For operation, the local MR transmit coils are located in a field of view of the at least one body coil.

The at least one power-feed coil may be embodied as at least one birdcage coil.

In another development, the MR device includes two-channel transmission architecture for the generation of a respective global, differently polarized B1 excitation field component, and at least two of the local MR transmit coils form a loop-butterfly structure.

In one embodiment, a method to operate an MR system is provided. At least two differently structured B1 field components (e.g., global B1 field components) of a global B1 excitation field are generated by at least one power-feed coil of the MR system. Different local MR transmit coils are inductively fed by the differently structured B1 field components, and the different local MR transmit coils generate differently structured local B1 excitation fields.

The method has the same advantages as the above-described apparatuses and may be embodied analogously.

For example, B1 field components of a global B1 excitation field, one of which is linearly polarized in the x-direction and one of which is linearly polarized in the y-direction, may be generated. At least one loop coil may be inductively coupled with one of these B1 field components, and at least one butterfly coil may be inductively coupled with the other of the B1 field components. The loop coil and the butterfly coil may generate local B1 excitation fields with linear polarization in accordance with the B1 field component of the global B1 excitation field inductively coupled therewith in each case.

### BRIEF DESCRIPTION OF THE DRAWINGS

For reasons of clarity, the same or similarly functioning elements have been given the same reference characters.

FIG. 1 is an angled view of a first exemplary magnetic resonance (MR) system with a first power-feed coil in the form of a body coil and with a first MR local coil system;

FIG. 2 is a sectional view transverse to a longitudinal axis of the body coil of the first MR system of a B1 field distribution inside the first body coil in the presence of a patient; and

FIG. 3 is an angled view of a second exemplary MR system with a second power-feed coil in the form of a body coil and a second MR local coil system.

### DETAILED DESCRIPTION

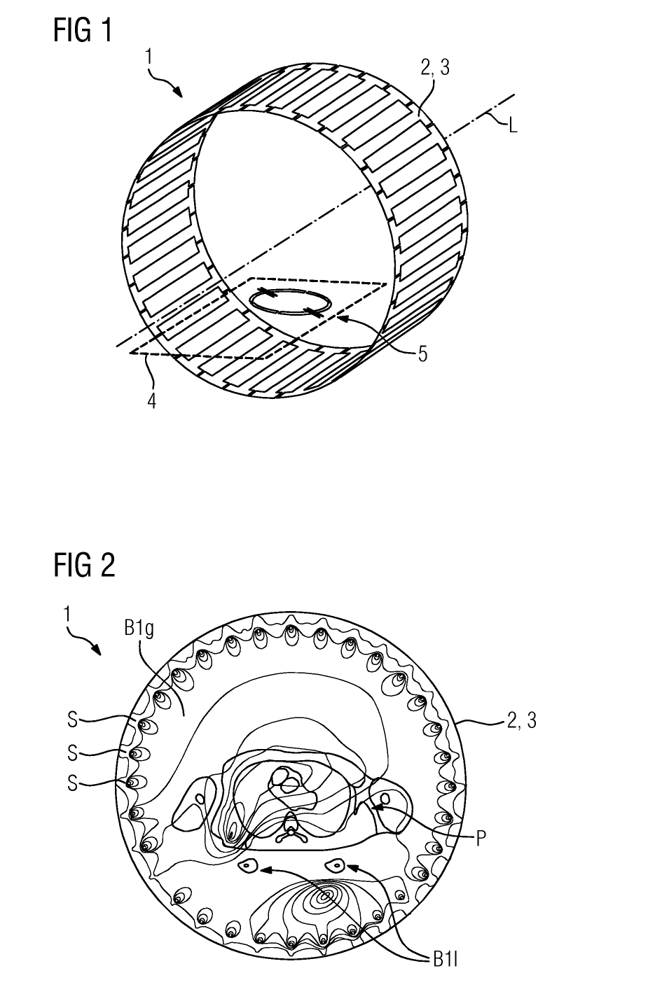

FIG. 1 shows a magnetic resonance (MR) system 1 including an MR device 2 with a whole-body coil as a power-feed coil in the form of a fixed birdcage-body coil 3 in the device with a longitudinal axis L. The longitudinal axis L corresponds, for example, to the fixed z-axis in the device. The MR system 1 further includes a first MR local coil system 4 arranged in a field of view of the body coil 3. The local coil system 4 includes a plurality of local MR transmit coils, of which at least two differ in shape. In this case, only one local MR transmit coil 5 (e.g., local coil) of the plurality of local MR transmit coils is shown.

The local MR transmit coil 5 is shown here in the form of a planar, circular coil (“loop”), which is inductively and hence wirelessly coupled with a B1 excitation field generated by the birdcage body coil 3. The coupling is resonant in order to keep losses low. The inductive coupling greatly simplifies the system design due to the omission of feed lines.

The local MR transmit coil 5 further includes a detuning circuit (not shown) by which the resonance frequency of the MR transmit coil 5 may be detuned, and hence, the coupling to the body coil 3 may be optionally activated and deactivated. With activated coupling, the MR transmit coil 5 concentrates the B1 excitation field of the body coil 3 in the vicinity of the MR transmit coil 5. With a deactivated MR transmit coil 5, there is no influence or only an insignificant influence on the B1 excitation field of the body coil 3.

The local MR transmit coil 5 may be operated as a pure transmit coil or as a transmit/receive coil.

FIG. 2 is a sectional view transverse to the longitudinal axis L of the body coil 3 showing a field distribution of a global B1 excitation field B1g inside the body coil 3 when a patient P is present. The B1 excitation field B1g is generated by the body coil 3 at feed points S of the body coil 3 distributed in a circular fashion around the longitudinal axis L.

The local MR transmit coil 5 may be arranged in the region of a spine of the patient P (e.g., integrated in a patient bench) and, with resonant inductive coupling, focuses or concentrates the global B1 excitation field B1g of the body coil 3 by generating an amplified local B1 excitation field B1l with a corresponding concentrated field distribution (e.g., in the region of the spine of the patient). For example, when the MR transmit coil 5 is positioned in the vicinity of an implant (not shown), the implant or a region surrounding the implant may be exposed to a higher field strength and hence, for example, achieve better resolution without increasing the SAR value of the patient P.

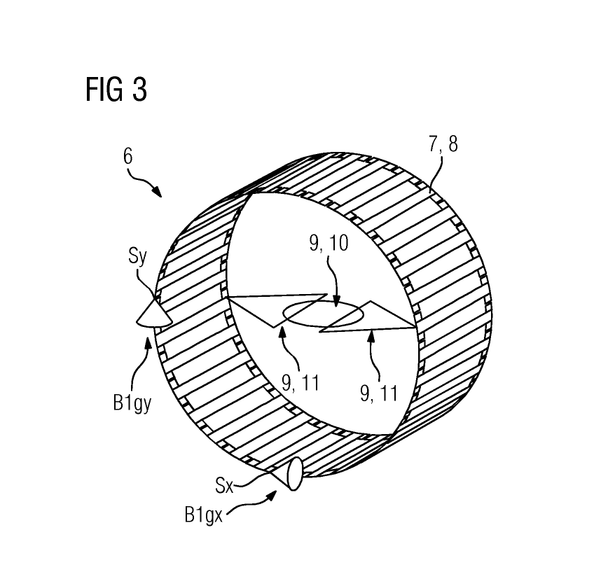

FIG. 3 is an angled view of a second exemplary MR system 6 including an MR device 7 with a second body coil 8 and a second MR local coil system 9. The MR local coil system 9 includes at least one loop coil 10 and one butterfly coil 11, which form a common flat loop-butterfly structure 10, 11 with the spatial arrangement shown. The butterfly coil 11 of the loop-butterfly structure 10, 11 includes two triangular conductor loops that are arranged mirror-symmetrically to the loop coil 10 and partially cover the same.

The MR device 7 has a two-channel transmission architecture and is configured to generate a B1 field component B1gx polarized in the global, x-direction and a global B1 field component B1gy polarized in the y-direction using and inside the body coil 7. The body coil 7 is divided into two individually controllable parts or regions, the respective feed points Sx and Sy of which generate the B1 field component B1gx polarized in the x-direction or the B1 field component B1gy polarized in the y-direction.

The B1 field component B1gx polarized in the x-direction is practically only coupled into the loop coil 10 or into the butterfly coil 11, while the B1 field component B1gy polarized in the y-direction is practically only coupled into the butterfly coil 11 or into the loop coil 10. The loop coil 10 and the butterfly coil 11 may, for example, generate local B1 excitation fields with a polarization corresponding to the polarization of the respective coupled-in B1 field component B1gx or B1gy.

The body coil 8 may also be operated analogously to the body coil 3 and, for example, generate a circularly polarized B1 excitation field B1g.

Although the invention was described and illustrated in detail by the exemplary embodiments shown, the invention is not restricted thereto, and other variations may be derived therefrom by the person skilled in the art without departing from the scope of protection of the invention.

For example, the local B1 excitation fields generated by the loop part and the butterfly part may also be differently polarized or unpolarized.

In one embodiment, only a polarization component of a circularly polarized B1 excitation field of a body coil acting in the x-direction may be received by the loop part or the butterfly part, and a polarization component acting in the y-direction may be received by the butterfly part or the loop part.

In general, “a”, “one”, etc. may be understood as being a singular or a plural, for example, in the sense of “at least one” or “one or more”, as long as this is not explicitly excluded (e.g., by the expression “exactly one” etc.).

A numerical indication may also include the indicated number exactly and also a customary tolerance range, as long as this is not explicitly excluded.

The elements and features recited in the appended claims may be combined in different ways to produce new claims that likewise fall within the scope of the present invention. Thus, whereas the dependent claims appended below depend from only a single independent or dependent claim, it is to be understood that these dependent claims may, alternatively, be made to depend in the alternative from any preceding or following claim, whether independent or dependent. Such new combinations are to be understood as forming a part of the present specification.

While the present invention has been described above by reference to various embodiments, it should be understood that many changes and modifications can be made to the described embodiments. It is therefore intended that the foregoing description be regarded as illustrative rather than limiting, and that it be understood that all equivalents and/or combinations of embodiments are intended to be included in this description.

1. A magnetic resonance (MR) local coil system comprising:
a plurality of local MR transmit coils that are inductively coupleable to at least one power-feed coil of an MR device,
wherein at least two local MR transmit coils of the plurality of local MR transmit coils are useable to generate local B1 excitation fields that are differently structured with respect to each other.

2. The MR local coil system of claim 1, wherein at least two local MR transmit coils of the plurality of local MR transmit coils are transmit coils that are planar with respect to each other and by which local B1 excitation fields with different polarization are generateable.

3. The MR local coil system of claim 1, wherein at least one local MR transmit coil of the plurality of local MR transmit coils has a loop-butterfly structure.

4. The MR local coil system of claim 3, wherein the at least one local MR transmit coil is operable as a pure transmit coil, as a transmit/receive coil, or as a combination thereof.

5. The MR local coil system of claim 1, wherein at least one local MR transmit coil of the plurality of local MR transmit coils comprises a detuning circuit by which the coupling to the at least one power-feed coil is activatable and deactivatable.

6. The MR local coil system of claim 2, wherein at least one local MR transmit coil of the plurality of local MR transmit coils has a loop-butterfly structure.

7. The MR local coil system of claim 2, wherein at least one local MR transmit coil of the plurality of local MR transmit coils comprises a detuning circuit by which the coupling to the at least one power-feed coil is activatable and deactivatable.

8. The MR local coil system of claim 3, wherein at least one local MR transmit coil of the plurality of local MR transmit coils comprises a detuning circuit by which the coupling to the at least one power-feed coil is activatable and deactivatable.

9. The MR local coil system of claim 4, wherein at least one local MR transmit coil of the plurality of local MR transmit coils comprises a detuning circuit by which the coupling to the at least one power-feed coil is activatable and deactivatable.

10. A magnetic resonance (MR) system comprising:
an MR device comprising at least one power-feed coil and at least one local MR local coil system,
wherein the at least one local MR local coil system comprises:
a plurality of local MR transmit coils that are inductively coupleable to at least one power-feed coil of the MR device, wherein at least two local MR transmit coils of the plurality of local MR transmit coils are useable to generate local B1 excitation fields that are differently structured with respect to each other,
wherein the plurality of local MR transmit coils of the at least one local MR local coil system are inductively coupleable with the at least one power-feed coil,
wherein the MR device is configured for selective generation of differently structured global B1 field components of a global B1 excitation field that is generateable by the at least one power-feed coil, and
wherein different local MR transmit coils of the plurality of local MR transmit coils of the local MR local coil system are coupleable with differently structured global B1 field components.

11. The MR system of claim 10, wherein the plurality of local MR transmit coils are configured to generate a local B1 excitation field that is similar to the structured global B1 field components coupled therewith in each case.

12. The MR system of claim 10, wherein the differently structured global B1 field components are B1 field components that are linearly polarized in the x-direction or the y-direction.

13. The MR system of claim 11, wherein the differently structured global B1 field components are B1 field components that are linearly polarized in the x-direction or the y-direction.

14. A method for operating a magnetic resonance (MR) system, the method comprising:
generating, by at least one power-feed coil of the MR system, at least two differently structured B1 field components of a global B1 excitation;
feeding different local MR transmit coils inductively, the feeding comprising using the at least two differently structured B1 field components; and
generating, with the different local MR transmit coils, differently structured local B1 excitation fields.

15. The method of claim 14, further comprising:
generating B1 field components of a global B1 excitation field, one of the B1 field components being linearly polarized in the x-direction and another of the B1 field components being linearly polarized in the y-direction, wherein at least one loop coil is inductively coupled with one of the B1 field components, and at least one butterfly coil is inductively coupled with another of the B1 field components; and
generating, by the at least one loop coil and the at least one butterfly coil, local B1 excitation fields with a linear polarization corresponding to the respective B1 field component coupled therewith of the global B1 excitation field.
